(19) United States
(12) Patent Application Publication
(10) Pub. No.: US 2024/0327968 A1
(43) Pub. Date: Oct. 3, 2024

(54) THERMAL CHEMICAL VAPOR DEPOSITION DEVICE WITH SINGLE FURNACE AND MANUFACTURING METHOD OF TRANSITION METAL DICHALCOGENIDE WITH THIS DEVICE

(71) Applicant: Research & Business Foundation SUNGKYUNKWAN UNIVERSITY, Suwon-si (KR)

(72) Inventors: Tae Sung KIM, Suwon-si (KR); Aydin KUBRA, Suwon-si (KR); Bahit GULGUN, Suwon-si (KR)

(73) Assignee: Research & Business Foundation SUNGKYUNKWAN UNIVERSITY, Suwon-si (KR)

(21) Appl. No.: 18/618,333

(22) Filed: Mar. 27, 2024

(30) Foreign Application Priority Data
Mar. 30, 2023 (KR) 10-2023-0042103

(51) Int. Cl. C23C 8/08; C23C 16/56; F27B 9/40

(52) U.S. Cl. CPC C23C 8/08; C23C 16/56; F27B 9/40

(57) ABSTRACT

The present invention discloses a metal sulfurization device using a single furnace, comprising an internal quartz tube unit; an external quartz tube unit that is located outside the internal quartz tube unit; a single furnace that is outside the external quartz tube unit and is movable along the outside of the external quartz tube unit; and a single furnace location control unit that is capable of controlling a position of the single furnace, wherein the internal quartz tube part includes: a sulfur source part that supplies sulfur powder; a substrate part on which metal is deposited; a distance control part that is capable of controlling a distance between the sulfur source part and the substrate part; and a gas supply part that injects gas from the sulfur source part toward the substrate part.

### CROSS REFERENCE TO RELATED APPLICATION

The present application claims priority to Korean Patent Application No. 10-2023-0042103, filed on Mar. 30, 2023, the entire contents of which are incorporated herein for all purposes by this reference.

### BACKGROUND OF THE INVENTION

### Field of the Invention

The present invention relates to a thermal chemical vapor deposition device and a method for manufacturing transition metal dichalcogenide using the same, and more specifically, to a metal sulfurization device using a single furnace without a separate additional equipment and a method for manufacturing sulfurized metal using the same device.

### Description of the Related Art

Considering the existing method for manufacturing sulfide metals such as MoS₂, the temperature at which sulfur(S) sublimates and the temperature at which metals such as Mo sulfurization is carried out in different temperature ranges. Due to this, when performing the above process, two or more different furnaces must be used in the thermal chemical vapor deposition (TCVD) method.

As described above, an additional pair of magnets is required to synthesize using only a single furnace without using two or more furnaces. This is because, through the additional pair of magnets, it is possible to place sulfur at a point far away from the furnace where sulfurization is to be performed and then move the sulfur to the position required for sublimation.

As such, since the sublimation temperature of sulfur(S) powder differs from the synthesis temperature of metal sulfides such as MoS₂, either two or more furnaces are required in the TCVD process chamber. Alternatively, when using only one furnace, a pair of magnets is necessary to control the position of the sulfur(S) powder. When using conventional methods, a furnace or a pair of magnets is needed in addition to a single furnace, which is a fairly expensive system. Accordingly, there is a need for a method that can manufacture MoS₂ through TCVD using a single furnace without the above additional system.

### DOCUMENTS OF RELATED ART

(Patent Document 1) China patent Publication No. 115011925 A

### SUMMARY OF THE INVENTION

A technical object to be achieved by the present invention is to provide a metal sulfurization device using a single furnace without a separate additional equipment and a method for manufacturing sulfurized metal using the same.

According to an embodiment of the present invention, a metal sulfurization process can be performed in an existing thermal chemical vapor deposition (TCVD) device without expensive additional parts.

The technical objects to be achieved by the present invention are not limited to the technical objects mentioned above, and other technical objects not mentioned may be clearly understood by those skilled in the art from the following descriptions.

In order to achieve the above technical object, an embodiment of the present invention provides a metal sulfurization device using a single furnace.

A metal sulfurization device using a single furnace according to an embodiment of the present invention may comprise an internal quartz tube unit S10, an external quartz tube unit S20 that is located outside the internal quartz tube unit S10, a single furnace S30 that is outside the external quartz tube unit and is movable along the outside of the external quartz tube unit S20, and a single furnace location control unit that is capable of controlling the position of the single furnace S30, wherein the internal quartz tube part S10 includes a sulfur source part S11 that supplies sulfur powder, a substrate part S12 on which metal is deposited, a distance control part that is capable of controlling a distance between the sulfur source part S11 and the substrate part S12, and a gas supply part that injects gas in a direction from the sulfur source part S11 toward the substrate part S12.

In addition, according to an embodiment of the present invention, a metal sulfurization device using a single furnace may comprise a single furnace S30, an external quartz tube unit S20 that penetrates the single furnace, an internal quartz tube unit S10 that is located inside the external quartz tube unit S20, and a quartz tube location control unit that is capable of controlling locations of the external quartz tube unit S20 and internal quartz tube unit S10, wherein through the location control unit, the external quartz tube unit S20 and internal quartz tube unit S10 are movable along an inside of the single furnace S30, wherein the internal quartz tube unit S10 includes a sulfur source part S11 that supplies sulfur powder, a substrate part S12 on which metal is deposited, a distance control part that is capable of controlling a distance between the sulfur source part S11 and the substrate part S12, and a gas supply part that injects gas in a direction from the sulfur source part S11 toward the substrate part S12.

In addition, according to an embodiment of the present invention, the metal sulfurization device using a single furnace may further comprise a control unit that is capable of measuring temperatures of the sulfur source part S11 and substrate part S12 and controlling the single furnace location control unit and distance control part.

In order to achieve the above technical object, another embodiment of the present invention provides a method for manufacturing sulfurized metal using a single furnace.

A method for manufacturing sulfurized metal using a single furnace according to an embodiment of the present invention may use the above-described metal sulfurization device using a single furnace. It may comprise the steps of at the beginning of operation, arranging each part such that through the single furnace location control unit and the distance control part, the substrate part on which the metal is deposited is located between the sulfur source part and the single furnace, injecting gas in a direction from the sulfur source part toward the substrate part through the gas supply part, increasing a temperature of the single furnace, and moving the temperature-increased single furnace to the substrate part along the outside of the external quartz tube unit through the location control unit while the device is operating.

In addition, according to an embodiment of the present invention, in the step of arranging each part of the method for manufacturing sulfurized metal using a single furnace, the distance between the sulfur source part and the substrate part is controlled so that the temperature difference between the substrate part and the sulfur source part may be 580° C. to 620° C.

In addition, according to an embodiment of the present invention, in the step of arranging each part of the method for manufacturing sulfurized metal using a single furnace, the distance between the sulfur source part and the substrate part may be 25 cm to 40 cm.

In addition, according to an embodiment of the present invention, in the method for manufacturing sulfurized metal using a single furnace, the metal deposited on the substrate part may be a transition metal.

In addition, according to an embodiment of the present invention, in the method for manufacturing sulfurized metal using a single furnace, the transition metal may be Mo.

In addition, according to an embodiment of the present invention, in the method for manufacturing sulfurized metal using a single furnace, the gas may be an inert gas.

In addition, according to an embodiment of the present invention, in the method for manufacturing sulfurized metal using a single furnace, the gas may be supplied at a flow rate of 40 sccm to 60 sccm.

In addition, according to an embodiment of the present invention, in the method for manufacturing sulfurized metal using a single furnace, the step of increasing the temperature of the single furnace may be to increase the temperature of the single furnace to a temperature at which the metal is sulfurized.

In addition, according to an embodiment of the present invention, in the method for manufacturing sulfurized metal using a single furnace, the step of increasing the temperature of the single furnace may be to increase the single furnace to 700° C. to 800° C.

In addition, according to an embodiment of the present invention, the method for manufacturing sulfurized metal using a single furnace may further comprise, after the step of moving the temperature-increased single furnace S30 to the substrate part along the outside of the external quartz tube unit S20, the steps of maintaining the increased temperature for 10 to 50 minutes and cooling to room temperature.

### BRIEF DESCRIPTION OF THE DRAWINGS

FIG. 1 is a schematic diagram of a synthesis step of a MoS₂ thin film through a T-CVD method using a single furnace according to an embodiment of the present invention.

FIG. 2 is a schematic diagram schematically showing a metal sulfurization device using a single furnace according to an embodiment of the present invention.

FIG. 3 shows graphs and images of (a) a Raman spectroscopy result, (b) an optical microscope image, and (c) and (d) XPS analysis of the 3d of Mo and 2p of S core peak spectra for T-CVD synthesized MoS₂, respectively.

FIG. 4 shows graphs and images of (a) HRTEM characteristics of a cross section of a MoS₂ film, (b) a line profile of layer spacing indicating a lattice spacing in (a), (c) an EDS mapping of MoS₂ for confirming a chemical composition of Mo and S atoms, (d) an EDS line profile of MoS₂ along a red line in a STEM image.

FIG. 5 shows graphs and images of (a) HRTEM characteristics of a MoS₂ film with a layer showing lattice stripes, (b) an enlarged image of (a), (c) an FFT image of a MoS₂ film with a layer showing lattice stripes. (d) grain boundary crystals in a top view image of a layered MoS₂ film showing lattice fringes.

### DETAILED DESCRIPTION OF THE INVENTION

Hereinafter, the present invention will be explained regarding the accompanying drawings. The present invention, however, may be modified in various different ways, and should not be construed as limited to the embodiments set forth herein. Also, in order to clearly explain the present invention, portions that are not related to the present invention are omitted, and alike reference numerals are used to refer to similar elements throughout.

Throughout the specification, it will be understood that when an element is referred to as being “connected (accessed, contacted, coupled) to” another element, this includes not only cases where the elements are “directly connected,” but also cases where the elements are “indirectly connected” with another member therebetween. Also, it will be understood that when a component “includes” an element, unless stated otherwise, this does not mean that other elements are excluded, but that other elements may be further added.

The terminology used herein is for the purpose of describing certain embodiments only and is not intended to limit the present invention. The singular forms are intended to include the plural forms as well unless the context clearly indicates otherwise. In the specification, it will be understood that the terms “comprise” and “include” specify the presence of stated features, integers, steps, operations, elements, components, and/or combinations thereof, but do not preclude in advance the possibility of the presence or addition of one or more other features, integers, steps, operations, elements, components, and/or combinations.

Hereinafter, the embodiments of the present invention will be explained in detail with reference to the accompanying drawings.

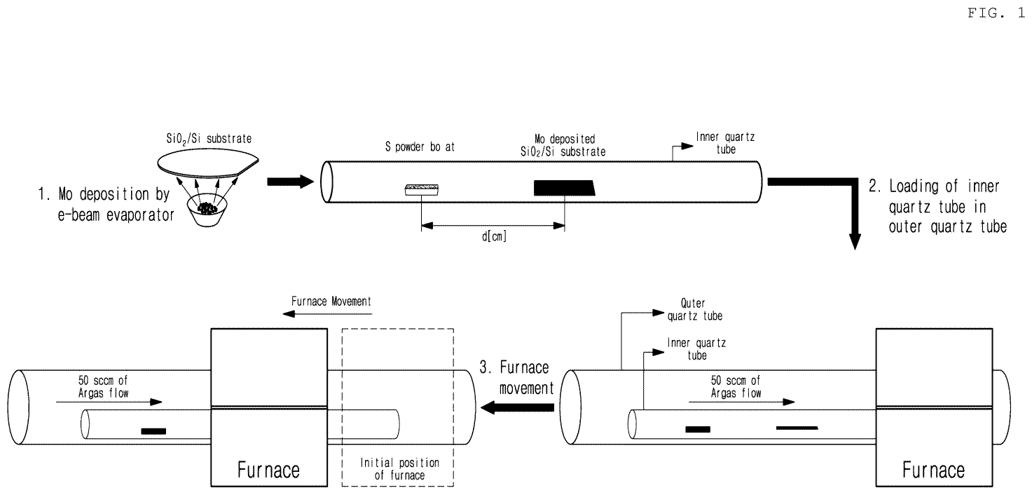

FIG. 1 is a schematic diagram of a synthesis step of a MoS₂ thin film through a T-CVD method using a single furnace according to an embodiment of the present invention.

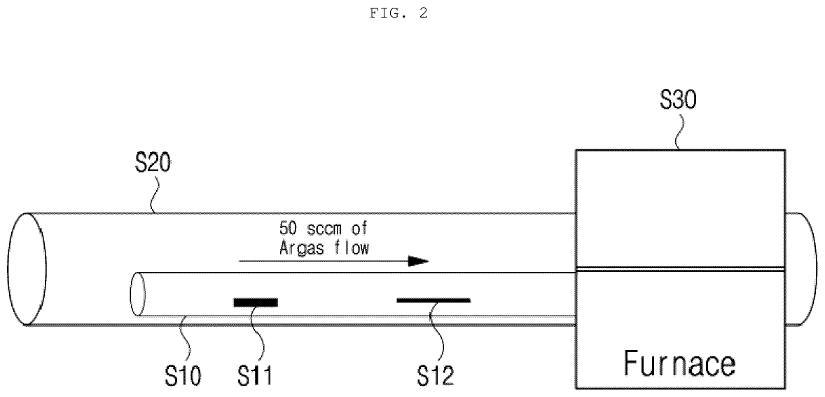

FIG. 2 is a schematic diagram schematically showing a metal sulfurization device using a single furnace according to an embodiment of the present invention.

With reference to FIGS. 1 and 2, a metal sulfurization device using a single furnace according to an embodiment of the present invention will be described.

As an example of the above embodiment, a metal sulfurization device using a single furnace may comprise an internal quartz tube unit S10, an external quartz tube unit S20 that is located outside the internal quartz tube unit S10, a single furnace S30 that is located outside the external quartz tube unit S20 and is movable along the outside of the external quartz tube unit S20, and a single furnace location control unit that is capable of controlling the position of the single furnace S30.

The internal quartz tube part S10 may include a sulfur source part S11 that supplies sulfur powder, a substrate part S12 on which metal is deposited, a distance control part that is capable of controlling a distance between the sulfur source part S11 and the substrate part S12, and a gas supply part that injects gas in a direction from the sulfur source part S11 toward the substrate part S12.

As an example of the above embodiment, a metal sulfurization device using a single furnace may comprise a single furnace, an external quartz tube unit that extends through the single furnace, an internal quartz tube unit that is located inside the external quartz tube unit, and a quartz tube location control unit that is capable of controlling locations of the external quartz tube unit and internal quartz tube unit.

Through the location control unit, the external quartz tube unit and internal quartz tube unit are movable along the inside of the single furnace.

The internal quartz tube unit may include a sulfur source part that supplies sulfur powder, a substrate part on which metal is deposited, a distance control part that is capable of controlling the distance between the sulfur source part and the substrate part, and a gas supply part that injects gas in a direction from the sulfur source part toward the substrate part.

As described above, concerning FIG. 2, the metal sulfurization device using a single furnace according to an embodiment of the present invention has a double tube-like structure in which the internal quartz tube unit S10 is located inside the external quartz tube unit S20. In addition, the single furnace S30 exists outside the external quartz tube unit S20, and the location control unit that can control the relative locations of the single furnace S30 and the quartz tube units S10 and S20 of the double-tube structure can be included.

As a method of controlling the relative locations of the single furnace S30 and quartz tube parts S10 and S20 of the double-tube structure, first, it may be controlled such that the single furnace S30 may move the outsides of the quartz tube units S10 and S20 of the double-tube structure.

As another method of controlling the relative locations of the single furnace S30 and quartz tube units S10 and S20 of the double-tube structure, it may control such that the quartz tube units S10 and S20 of the double-tube structure move the internal side of the single furnace S30.

Hereinafter, in case where it is described that the location of the single furnace is controlled, this means controlling the relative locations of the single furnace S30 and quartz tube units S10 and S20 of the double-tube structure by all methods including the above two methods.

The method for manufacturing sulfurized metal using a single furnace will be described later, but referring FIG. 1, the location of the metal sulfurization device using a single furnace may be operated in a way in which the location of the substrate part S12 on which the metal is deposited is controlled during the process of sulfurizing the metal.

The sulfur source part S11 serves to supply sulfur needed in the process of sulfurizing a metal.

In addition, the substrate part S12 on which the metal is deposited is r depositing a target metal to be sulfurized on the substrate.

The substrate may be a SiO₂/Si substrate, and the deposition method may be by depositing the metal on the substrate using an electron beam (E-beam) deposition method.

As an example of the above embodiment, the metal sulfurization device using a single furnace may further comprise a control unit that is capable of measuring temperatures of the sulfur source part S11 and substrate part S12 and controlling the single furnace location control unit and distance control part.

The distance between the sulfur source part S11 and the substrate part S12 may be controlled through the distance control part.

Controlling the distance between the sulfur source part S11 and the substrate part S12 is crucial for sulfurizing the metal using only a single furnace, thereby eliminating the need for separate expensive equipment.

This is related to the temperature gradient in heat transfer. The temperature gradient refers to the change in temperature passing through various building envelope materials or insulation materials as the outside temperature is transferred to the inside across the wall, just as water flows from a high place to a low place due to the action of gravity. In other words, in the process of heat transfer, the temperature of a corresponding part continuously drops as the distance from the heat source increases.

In general, sublimation of sulfur requires a temperature of about 150° C., but sulfurization of metals requires a higher temperature, so the metal is placed close to the heat source, and the sulfur is placed a little further away. In this way, even if only a single furnace is used, the sulfurization process of the metal can be successfully performed by placing the metal and sulfur in an appropriate position considering the temperature gradient.

As an example of the above embodiment, in the metal sulfurization device using a single furnace, the metal may include one or more selected from the group consisting of Mo, Cu, Cd, W, and Ag.

Mo, one of the metals, may generally be sulfurized at a temperature of 750° C., but sublimation of sulfur requires a temperature of about 150° C.

The distance may be controlled depending on the external environment, such as the temperature difference and temperature gradient between sulfur and metal.

In this case, if the distance between the heat source and the sulfur source part S11 is close and the temperature of the sulfur source part S11 is higher than 150° C., a problem may occur in which sulfur sublimates and exits the device before sulfurization of the metal occurs.

The rate of temperature loss per cm can be considered about the above distance.

The temperature loss in equipment such as TCVD is approximately 40° C./cm, and this value may also be confirmed through various other literature.

Therefore, considering the above-described temperature loss rate per cm, it is possible to roughly calculate at what distance the temperature required for the sublimation of a target material occurs in the current system.

Through the control unit, the temperatures of the sulfur source part S11 and substrate part S12 may be measured, and the single furnace control unit and distance control part may be controlled. Thus, the above-described problem can be prevented by continuously measuring the temperatures of the sulfur source part S11 and substrate part S12 during the process.

Therefore, when the metal is Mo, considering the temperature gradient, the distance between the sulfur source part S11 and the substrate part S12 may be controlled such that a temperature difference between the substrate part S12 and the sulfur source part SS11 is 580° C. to 620° C.

In addition, when the metal is Mo, taking the temperature gradient into consideration, the distance between the sulfur source part S11 and the substrate part S12 may be controlled to be 25 cm to 40 cm.

In the metal sulfurization device using a single furnace described above, the external quartz tube unit S20 and internal quartz tube unit S10 may use glass tubes, plastic tubes, ceramic tubes, carbon fiber tubes, metal tubes, etc. instead of quartz tubes.

As described above, the metal sulfurization device using a single furnace uses only one furnace and may also perform the metal sulfurization process without expensive additional parts in the existing thermal chemical vapor deposition (TCVD) device. Accordingly, the sulfurization process may be carried out in a simpler process and has an advantage in terms of price as well.

A method for manufacturing sulfurized metal using a single furnace according to another embodiment of the present invention will be described.

As an example of the above embodiment, a method for manufacturing sulfurized metal using a single furnace may use the above-described metal sulfurization device using a single furnace and comprise the steps at the beginning of the operation, arranging each part such that through the single furnace location control unit and the distance control part, the substrate part S12 on which the metal is deposited is located between the sulfur source part S11 and the single furnace S30, injecting gas in a direction from the sulfur source part S11 toward the substrate part S12 through the gas supply part, increasing a temperature of the single furnace S30, and moving the temperature-increased single furnace S30 to the substrate part S12 along the outside of the external quartz tube unit S20 through the location control unit while the device is operating.

Through the step of arranging each part, the substrate part S12 on which the metal is deposited is located between the sulfur source part S11 and the single furnace S30 at the beginning of operation.

As an example of the above, the sulfur source part S11 may be arranged on the left, the substrate part S12 on which the metal is deposited may be arranged in the center, and the single furnace S30 may be arranged on the right.

As another example, the single furnace S30 may be arranged on the left, the substrate part S12 on which the metal is deposited may be arranged in the center, and the sulfur source part S11 may be arranged on the right in case gas flow is from right to left.

The distance between the sulfur source part S11 and the substrate part S12 must be controlled quite importantly, in order to sulfurize the metal using only a single furnace without using separate expensive equipment.

This is related to the temperature gradient in heat transfer. The temperature gradient refers to the change in temperature passing through various building envelope materials or insulation materials as the outside temperature is transferred to the inside across the wall, just as water flows from a high place to a low place due to the action of gravity. In other words, in an embodiment of the present invention, in the process of heat transfer, the temperature of a corresponding part continuously drops as the distance from the heat source increases.

In general, sublimation of sulfur requires a temperature of about 150° C., but sulfurization of metals requires a higher temperature, so the metal is placed close to the heat source, and the sulfur is placed a little further away. In this way, even if only a single furnace is used, the sulfurization process of the metal can be successfully performed by placing the metal and sulfur in an appropriate position considering the temperature gradient.

As an example of the above embodiment, in the method for manufacturing sulfurized metal using a single furnace, the metal deposited on the substrate part is a transition metal.

As an example of the above embodiment, in the method for manufacturing sulfurized metal using a single furnace, the transition metal includes one or more selected from the group consisting of Mo, Cu, Cd, W, and Ag.

Mo, one of the transition metals, may generally be sulfurized at a temperature of 750° C., but sublimation of sulfur requires a temperature of about 150° C.

The distance may be controlled depending on the external environment, such as the temperature difference and temperature gradient between sulfur and metal.

In the case of increasing the temperature of the single furnace S30, if the distance between the single furnace S30 and the sulfur source part S11 is close and the temperature of the sulfur source part S11 is higher than 150° C., a problem may occur in which sulfur sublimates and exits the device before sulfurization of the metal occurs.

Through the control unit, the temperatures of the sulfur source part S11 and substrate part S12 may be measured, and the single furnace control unit and distance control part may be controlled. The temperatures of the sulfur source part S11 and substrate part S12 are continuously measured during the process, and through this, the above-described problem can be prevented by controlling the relative location between the single furnace S30, the sulfur source part S11, and the substrate part S12 on which the metal is deposited.

As an example of the above embodiment, in the step of arranging each part of the method for manufacturing sulfurized metal using a single furnace, the distance between the sulfur source part S11 and the substrate part S12 is controlled so that the temperature difference between the substrate part S12 and the sulfur source part S11 is equal to the difference between the sulfurization temperature of the metal and the sublimation temperature of the sulfur.

As an example of the above embodiment, in the step of arranging each part of the method for manufacturing sulfurized metal using a single furnace, the distance between the sulfur source part S11 and the substrate part S12 is controlled so that the temperature difference between the substrate part S12 and the sulfur source part S11 is 580° C. to 620° C.

The temperature difference of 580° C. to 620° C. is an example of an embodiment of the present invention in which such temperature difference is applied as the difference between the sulfurization temperature of the metal and the sublimation temperature of the sulfur described above in a case where the metal is Mo.

Since Mo may generally be sulfurized in a temperature range of approximately 750° C., a temperature difference of 580° C. to 620° C., which is the difference from the temperature range of approximately 150° C., which is the temperature at which sulfur sublimates, may be derived.

As an example of the above embodiment, in the step of arranging each part of the method for manufacturing sulfurized metal using a single furnace, the distance between the sulfur source part S11 and the substrate part S12 is 25 cm to 40 cm.

The distance of 25 cm to 40 cm is generated assuming that the metal is Mo, and considering the temperature gradient, the distance between the sulfur source part S11 and the substrate part S12 refers to a distance range such that the distance between the sulfur source part S11 and the substrate part S12 has a temperature difference of 580° C. to 620° C. as described above.

As an example of the above embodiment, in the method for manufacturing sulfurized metal using a single furnace, the gas is an inert gas.

As an example of the above embodiment, in the method for manufacturing sulfurized metal using a single furnace, the gas is supplied at a flow rate of 40 sccm to 60 sccm.

As an example of the above embodiment, in the method for manufacturing sulfurized metal using a single furnace, the step of increasing the temperature of the single furnace S30 is to increase the temperature of the single furnace S30 to a temperature at which the metal is sulfurized.

As an example of the above embodiment, in the method for manufacturing sulfurized metal using a single furnace, the step of increasing the temperature of the single furnace S30 is to increase the single furnace S30 to 700° C. to 800° C.

The temperature range of 700° C. to 800° C. refers to the temperature range at which Mo is sulfurized, assuming that the metal is Mo.

As an example of the above embodiment, the method for manufacturing sulfurized metal using a single furnace may further comprise, after the step of moving the temperature-increased single furnace S30 to the substrate part along the outside of the external quartz tube unit S20, the steps of maintaining the increased temperature for 10 to 50 minutes and cooling to room temperature.

In the above-described method for manufacturing sulfurized metal using a single furnace, the external quartz tube unit S20 and the internal quartz tube unit S10 may use glass tubes, plastic tubes, ceramic tubes, carbon fiber tubes, metal tubes, etc., instead of quartz tubes.

As described above, the method for manufacturing sulfurized metal using a single furnace uses only one the furnace may also perform the metal sulfurization process without expensive additional parts in the existing thermal chemical vapor deposition (T-CVD) device. Accordingly, the sulfurization process may be carried out in a simpler process and has an advantage in terms of price as well.

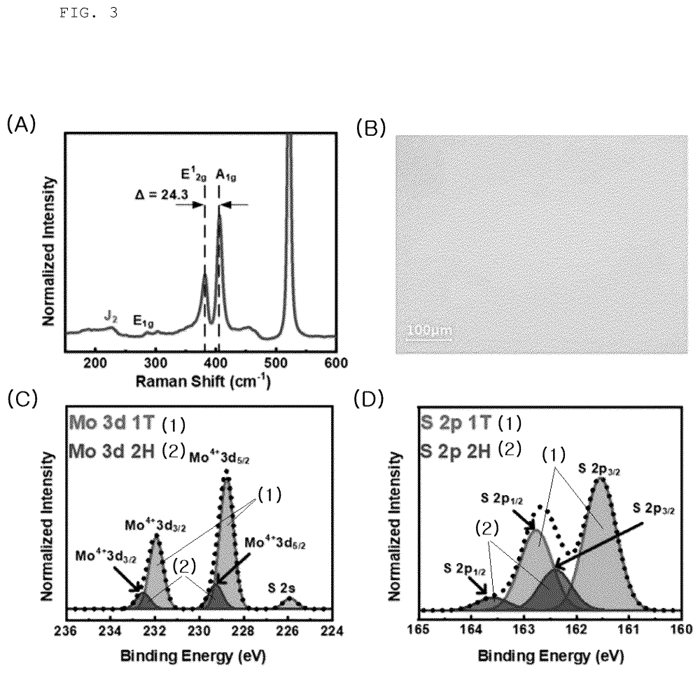

FIG. 3 shows graphs and images of (a) a Raman spectroscopy result, (b) an optical microscope image, and (c) and (d) XPS analysis of the 3d of Mo and 2p of S core peak spectra for T-CVD synthesized MoS₂, respectively.

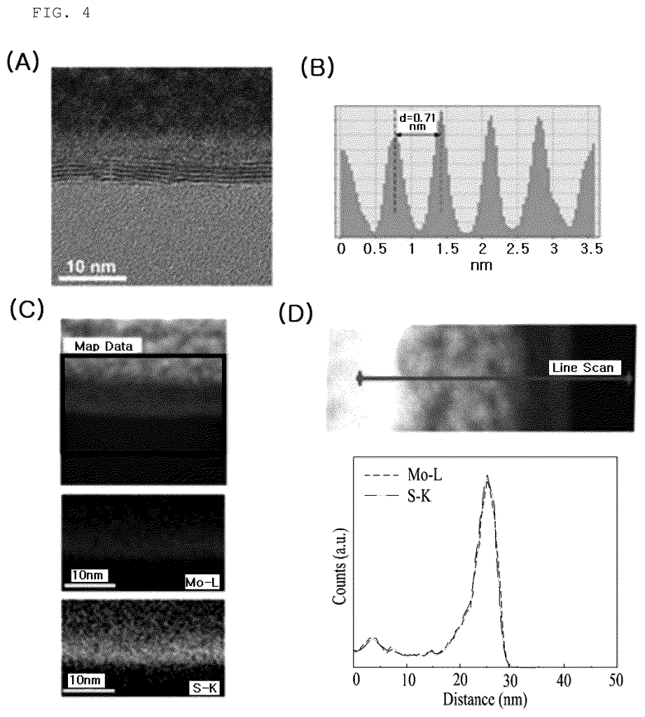

FIG. 4 shows graphs and images of (a) HRTEM characteristics of a cross section of a MoS₂ film, (b) a line profile of layer spacing indicating a lattice spacing in (a), (c) an EDS mapping of MoS₂ for confirming a chemical composition of Mo and S atoms, (d) an EDS line profile of MoS₂ along a red line in a STEM image.

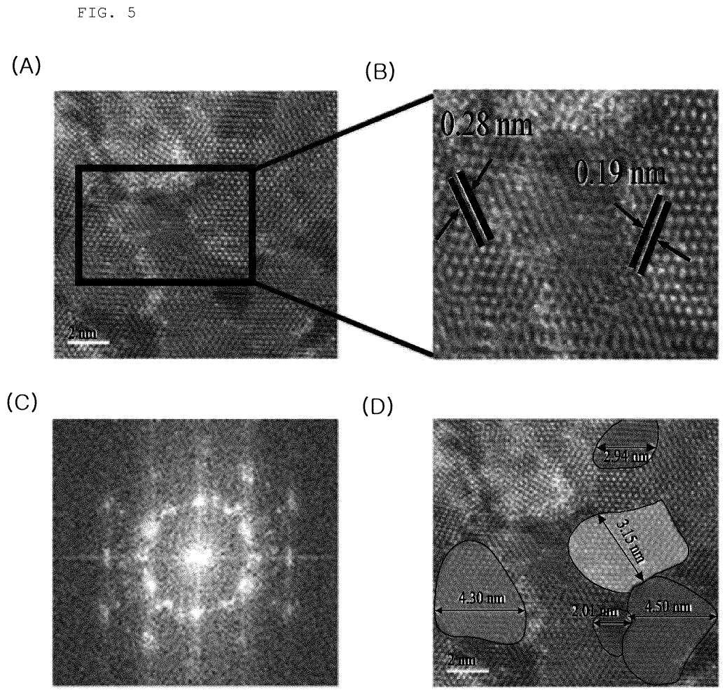

FIG. 5 shows graphs and images of (a) HRTEM characteristics of a MoS₂ film with a layer showing lattice stripes, (b) an enlarged image of (a), (c) an FFT image of a MoS₂ film with a layer showing lattice stripes. (d) grain boundary crystals in a top view image of a layered MoS₂ film showing lattice fringes.

Regarding FIGS. 3 to 5, Experimental Examples 1 to 3 are described below.

### Experimental Example 1. Raman and XPS Analysis

The Raman spectrum in FIG. 3 (a) was identified as two main peaks: in-plane E¹_{2g} (381.4 cm⁻¹) and out-of-plane A_{1g} (405.7 cm-1). These sharp Raman peaks indicate a better crystallinity of the material. In addition, the distance between the E¹_{2g} and A_{1g} peaks provides information about the number of layers in MOS₂.

It can be seen from the distance of 24.3 cm⁻¹ shown in FIG. 3 (a) that MoS₂ synthesis using T-CVD has 5 to 6 layers. Additional 2H structure-related peaks at 285.2 cm⁻¹ and 1T structure-related peaks at 227.2 cm⁻¹ were obtained as E_{1g} and J₂ peaks, respectively, in the Raman spectrum.

The optical microscope image is shown in FIG. 3 (b) shows that MoS₂ on the SiO₂/Si substrate completely covers the substrate surface by forming a continuous and uniform layer.

As a result, the chemical content of MOS₂ was identified by XPS analysis, and the Mo 3d core peak spectrum was shown in FIG. 3 (c) and the S 2p core peak spectrum as shown in FIG. 3 (d). The two distinct peaks at 231.9 eV and 228.8 eV correspond to the binding energies of 3d_{3/2} and 3d_{5/2} of Most, which confirms the presence of 1T structure in MoS₂.

In addition to these peaks, there are two other distinct peaks at 232.5 eV and 229.3 eV for the binding energies of 3d_{3/2} and 3d_{5/2} of Mo⁴⁺, implying the presence of a 2H structure in MOS₂. A relatively weak peak located at 226 eV shows the S 2s binding energy of MoS₂. The S 2p_{1/2} and S 2p_{3/2} peaks correspond to 162.8 eV and 161.5 eV shown in FIG. 3(d) indicates the formation of 1T-MOS₂ in the material structure.

In addition, the S 2p peak of MoS₂, which is a 2H structure, was found at 163.6 eV and 162.4 eV. According to the Raman and XPS analysis results, it can be said that 1T and 2H structures exist together in the synthesized MOS₂.

### Experimental Example 2. High-Resolution Transmission Electron Microscopy (HRTEM) Analysis

The MoS₂ thin film was analyzed by high-resolution transmission electron microscopy (HRTEM) method to indicate the crystal structure shown in FIG. 4.

FIG. 4 (a) presents the MoS₂ structure with 5 to 6 layers with a thickness of 4 nm or less, which was also identified in the Raman spectroscopy study according to the difference between the two phonon peaks.

FIG. 4 (b) shows the line profile of MoS₂ corresponding to the cyan line shown in FIG. 4 (a). The line profiling results showed that the distance between MoS₂ layers was 0.71 nm for this CVD method.

In addition, the elemental composition of MOS₂ was analyzed using an energy-dispersive spectrometer (EDS). The EDS mapping in FIG. 4 (c) indicated Mo and S as the main components, this is because uniform dispersion of Mo and S constituent elements was observed throughout the thin film according to the red map area. EDS line scanning profile analysis was used to confirm that MoS₂ was synthesized uniformly. As can be seen in FIG. 4 (d), the overlapping area between Mo and S means that MoS₂ was synthesized uniformly.

### Experimental Example 3. HRTEM Plan View Imaging Analysis to Confirm Crystallinity of MoS₂ Thin Films

To confirm the crystallinity of the MoS₂ thin film, further analysis was performed using HRTEM plan view imaging. MoS₂ was transferred onto the TEM grid using the PMMA-assisted water transfer method.

The HRTEM images in FIGS. 5 (a) and 5 (b) show a hexagonal lattice of 2H-MOS₂ and an octahedral lattice of 1T-MoS₂ with lattice spacings up to 2.8 Å (100) and up to 1.9 Å (110). The hexagonal and octahedral structures of the synthesized MoS₂ thin film were further confirmed by fast Fourier transform (FFT) results, which are illustrated in FIG. 5 (c). HRTEM shows the grain size of MoS₂ varying from 2.0 nm to 4.5 nm in FIG. 5 (d).

The description of the present invention is used for illustration and those skilled in the art will understand that the present invention can be easily modified to other detailed forms without changing the technical spirit or an essential feature thereof. Therefore, the aforementioned exemplary embodiments are illustrative in all aspects and are not limited. For example, each component described as a single type may be implemented to be distributed and similarly, components described to be distributed may also be implemented in a combined form.

The scope of the invention is to be defined by the scope of claims provided below, and all variations or modifications that can be derived from the meaning and scope of the claims as well as their equivalents are to be interpreted as being encompassed within the scope of the present invention.

According to an embodiment of the present invention, a metal sulfurization device using a single furnace and a method for manufacturing sulfurized metal using the same can be provided without a separate additional system.

Therefore, the sulfurization process of metal can be performed in an existing thermal chemical vapor deposition (TCVD) device without expensive additional parts.

The effects of the present disclosure are not limited to the above-mentioned effects, and it should be understood that the effects of the present disclosure include all effects that could be inferred from the configuration of the invention described in the detailed description of the invention or the appended claims.

### DESCRIPTION OF REFERENCE NUMERALS

S10: internal quartz tube unit
S11: sulfur source part
S12: substrate part
S20: external quartz tube unit
S30: single furnace

What is claimed is:

1. A metal sulfurization device using a single furnace, comprising:
an internal quartz tube unit;
an external quartz tube unit that is located outside the internal quartz tube unit;
a single furnace that is outside the external quartz tube unit and is movable along the outside of the external quartz tube unit; and
a single furnace location control unit that is capable of controlling the position of the single furnace,
wherein the internal quartz tube part includes:
a sulfur source part that supplies sulfur powder;
a substrate part on which metal is deposited;
a distance control part that is capable of controlling the distance between the sulfur source part and the substrate part; and
a gas supply part that injects gas from the sulfur source part toward the substrate part.

2. A metal sulfurization device using a single furnace, comprising:
a single furnace;
an external quartz tube unit that extends across the single furnace;
an internal quartz tube unit that is located inside the external quartz tube unit; and
a quartz tube location control unit that is capable of controlling the locations of the external quartz tube unit and internal quartz tube unit,
wherein through the location control unit, the external quartz tube unit and internal quartz tube unit are movable along an inside of the single furnace,
wherein the internal quartz tube unit includes:
a sulfur source part that supplies sulfur powder;
a substrate part on which metal is deposited;
a distance control part that is capable of controlling the distance between the sulfur source part and the substrate part; and
a gas supply part that injects gas in a direction from the sulfur source part toward the substrate part.

3. The metal sulfurization device of claim 1, further comprise a control unit that is capable of measuring temperatures of the sulfur source part and substrate part and controlling the single furnace location control unit and distance control part.

4. The metal sulfurization device of claim 1, wherein the metal includes one or more selected from the group consisting of Mo, Cu, Cd, W, and Ag.

5. A method for manufacturing sulfurized metal using a single furnace which uses the metal sulfurization device using a single furnace of claim 1, the method comprising the steps of:
at the beginning of the operation, arrange each part such that through the single furnace location control unit and the distance control part, the substrate part on which the metal is deposited is located between the sulfur source part and the single furnace;
injecting gas in a direction from the sulfur source part toward the substrate part through the gas supply part;
increasing the temperature of the single furnace; and
moving the temperature-increased single furnace to the substrate part along the outside of the external quartz tube unit through the location control unit while the device is operating.

6. The method of claim 5, wherein the metal deposited on the substrate part is a transition metal.

7. The method of claim 6, wherein the transition metal includes one or more selected from the group consisting of Mo, Cu, Cd, W, and Ag.

8. The method of claim 5, wherein in the step of arranging each part, a distance between the sulfur source part and the substrate part is controlled so that a temperature difference between the substrate part and the sulfur source part is equal/similar to a difference between a sulfurization temperature of the metal and a sublimation temperature of the sulfur.

9. The method of claim 5, wherein in the step of arranging each part, a distance between the sulfur source part and the substrate part is controlled so that a temperature difference between the substrate part and the sulfur source part is 580° C. to 620° C.

10. The method of claim 5, wherein in the step of arranging each part, a distance between the sulfur source part and the substrate part is 25 cm to 40 cm.

11. The method of claim 5, wherein the gas is an inert gas.

12. The method of claim 5, wherein the gas is supplied at a flow rate of 40 sccm to 60 sccm.

13. The method of claim 5, wherein the step of increasing the temperature of the single furnace is to increase the temperature of the single furnace to a temperature at which the metal is sulfurized.

14. The method of claim 5, wherein the step of increasing the temperature of the single furnace is to increase the single furnace to 700° C. to 800° C.

15. The method of claim 5, further comprising, after the step of moving the temperature-increased single furnace to the substrate part along the outside of the external quartz tube unit, the steps of:
maintaining the increased temperature for 10 to 50 minutes; and
cooling to room temperature.
